(19) United States
(12) Patent Application Publication
(10) Pub. No.: US 2024/0304637 A1
(43) Pub. Date: Sep. 12, 2024

(54) IMAGE SENSORS AND METHOD OF MANUFACTURING THE SAME

(71) Applicant: SAMSUNG ELECTRONICS CO., LTD., Suwon-si (KR)

(72) Inventors: Sung-Yool CHOI, Daejeon (FR); Seung Hun Han, Daejeon (KR); Cheolmin Park, Daejeon (KR); Hyeok Jun Jin, Daejeon (KR)

(73) Assignees: SAMSUNG ELECTRONICS CO., LTD., Suwon-si (KR); KOREA ADVANCED INSTITUTE OF SCIENCE AND TECHNOLOGY, Daejeon (KR)

(21) Appl. No.: 18/594,964

(22) Filed: Mar. 4, 2024

(30) Foreign Application Priority Data
Mar. 6, 2023 (KR) 10-2023-0029274

(51) Int. Cl. H01L 27/146

(52) U.S. Cl. CPC H01L 27/1461; H01L 27/1463; H01L 27/14636; H01L 27/14696

(57) ABSTRACT

An image sensor includes: a semiconductor substrate including a top surface and a bottom surface; a two-dimensional (2D) material layer on the top surface of the semiconductor substrate and including molybdenum disulfide (MoS₂); and a top absorber on a top surface of the 2D material layer and including graphene, wherein the semiconductor substrate includes silicon doped with a p-type impurity, the 2D material layer has n-type conductivity, and the semiconductor substrate and the 2D material layer are configured to form a p-n diode.

### CROSS-REFERENCE TO RELATED APPLICATION

This application is based on and claims priority under 35 U.S.C. § 119 to Korean Patent Application No. 10-2023-0029274, filed on Mar. 6, 2023, in the Korean Intellectual Property Office, the disclosure of which is incorporated by reference herein in its entirety.

### BACKGROUND

The present disclosure relates to an image sensor and a method of manufacturing the same, and more particularly, to an image sensor including a photodiode having a hybrid structure of a two-dimensional (2D) material and a three-dimensional (3D) material.

An image sensor is a device that converts an optical image signal into an electrical signal. The image sensor includes a plurality of pixels, each of which includes a photodiode region that receives incident light and converts the light into an electrical signal. As integration of the image sensor increases, the size of each pixel decreases, thereby resulting in image quality degradation, especially in a low-light environment.

### SUMMARY

Example embodiments provide an image sensor having excellent photoelectric conversion efficiency and fast response speed, and a method of manufacturing the image sensor.

According to an aspect of one or more example embodiments, an image sensor includes: a semiconductor substrate including a top surface and a bottom surface; a two-dimensional (2D) material layer on the top surface of the semiconductor substrate and including molybdenum disulfide (MoS₂); and a top absorber on a top surface of the 2D material layer and including graphene, wherein the semiconductor substrate includes silicon doped with a p-type impurity, wherein the 2D material layer has n-type conductivity, and the semiconductor substrate and the 2D material layer are configured to form a p-n diode.

According to an aspect of one or more example embodiments, an image sensor includes: a semiconductor substrate including a top surface and a bottom surface; a two-dimensional (2D) material layer on the top surface of the semiconductor substrate and including molybdenum disulfide (MoS₂); and a top absorber on a top surface of the 2D material layer and including graphene, wherein the 2D material layer includes 2D sheets including from two to five layers stacked in a vertical direction on the top surface of the semiconductor substrate, and the top absorber comprises a monolayer of graphene.

According to an aspect of one or more example embodiments, an image sensor includes a plurality of pixels, wherein each of the plurality of pixels comprises: a doped region in a semiconductor substrate and including a p-type impurity; a two-dimensional (2D) material layer on a top surface of the semiconductor substrate and including molybdenum disulfide (MoS₂); a top absorber on a top surface of the 2D material layer and including graphene; a first electrode on the top absorber; and a second electrode on a bottom surface of the semiconductor substrate and electrically connected to the doped region, wherein the 2D material layer includes 2D sheets including from two to five layers stacked in a vertical direction on the top surface of the semiconductor substrate, and the top absorber comprises a monolayer of graphene.

### BRIEF DESCRIPTION OF THE DRAWINGS

The above and other aspects and features will be more apparent from the following description of example embodiments taken in conjunction with the accompanying drawings in which:

FIG. 1 is a perspective view schematically showing an image sensor according to one or more example embodiments;

FIG. 2 is a cross-sectional view of the image sensor of FIG. 1 according to one or more example embodiments;

FIG. 3 is a schematic view showing a schematic energy band structure of an image sensor according to one or more example embodiments;

FIG. 4 is a cross-sectional view showing an image sensor according to one or more example embodiments;

FIG. 5 is a cross-sectional view showing an image sensor according to one or more example embodiments;

FIG. 6 is a graph showing a voltage-current behavior with respect to a p-n diode formation according to one or more example embodiments;

FIG. 7 is a graph showing a voltage-photocurrent behavior of an image sensor based on a photodiode according to one or more example embodiments;

FIG. 8 is a graph showing a photocurrent with respect to an incident power of an image sensor according to one or more example embodiments;

FIG. 9 is a graph showing responsivity with respect to incident power of an image sensor according to one or more example embodiments;

FIG. 10 is a graph showing responsivity and a quantum efficiency with respect to an incident light wavelength of an image sensor according to one or more example embodiments;

FIG. 11 is a graph showing a high-speed response time of several tens of nanoseconds of an image sensor according to one or more example embodiments;

FIGS. 12, 13 and 14 are cross-sectional views for explaining a method of manufacturing an image sensor according to one or more example embodiments; and

FIG. 15 is a block diagram of an image sensor according to one or more example embodiments.

### DETAILED DESCRIPTION

Hereinafter, example embodiments will be described with reference to the accompanying drawings. The same reference numerals are used for the same components in the drawings, and duplicate descriptions thereof are omitted.

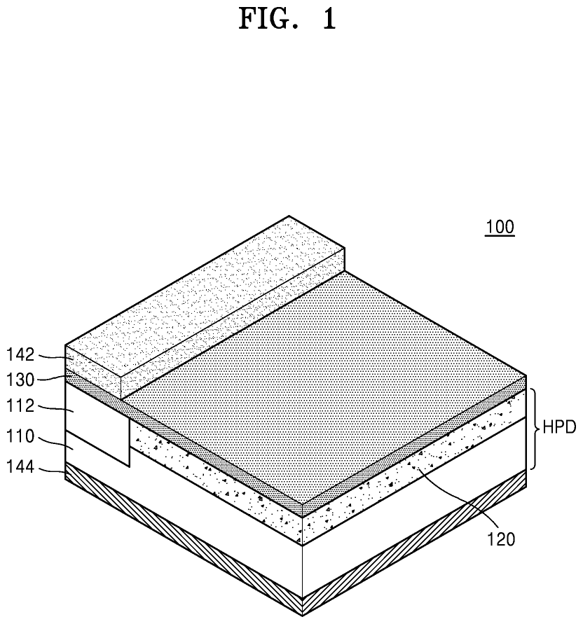

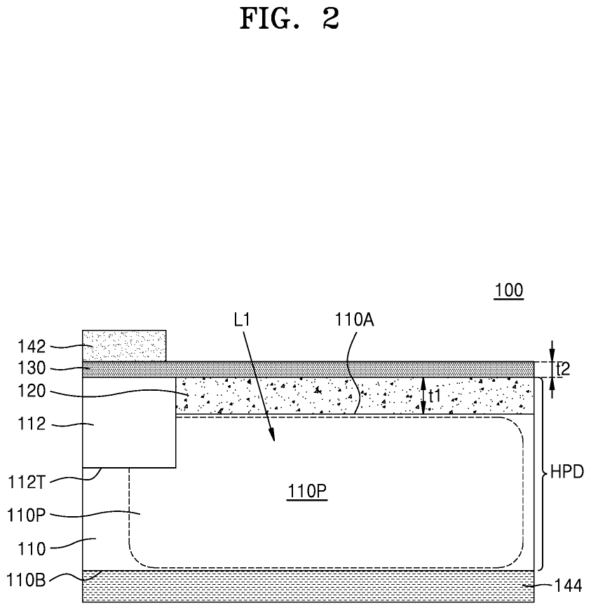

FIG. 1 is a perspective view schematically showing an image sensor 100 according to one or more example embodiments, and FIG. 2 is a cross-sectional view of the image sensor 100 of FIG. 1 according to one or more example embodiments.

Referring to FIGS. 1 and 2, the image sensor 100 may include a semiconductor substrate 110, a two-dimensional (2D) material layer 120, a top absorber 130, a first electrode 142, and a second electrode 144.

The semiconductor substrate 110 may include a silicon substrate doped with a p-type impurity. The semiconductor substrate 110 may include a first surface 110A (for example, a top surface) and a second surface 110B (for example, a bottom surface) opposite the first surface 110A. A plurality of pixel regions may be provided in the semiconductor substrate 110 into which light L1 may be incident from outside of the image sensor 100.

A doped region 110P doped with a p-type impurity may be disposed inside the semiconductor substrate 110. The doped region 110P may be formed by injecting boron (B) or gallium (Ga) ions into the semiconductor substrate 110. The doped region 110P may form a part of a hybrid photodiode HPD.

The two-dimensional (2D) material layer 120 may be disposed on the first surface 110A of the semiconductor substrate 110. In one or more example embodiments, the 2D material layer 120 may have a 2D layered structure and include, for example, molybdenum disulfide (MoS₂). In one or more example embodiments, the 2D material layer 120 may have n-type conductivity.

In one or more example embodiments, the 2D material layer 120 may include 2D sheets of 2 to 5 layers. Herein, a 2D sheet of 1 layer may have a structure where unit cells are repeatedly disposed two-dimensionally (e.g., along an x-y plane), and one molybdenum atomic layer may be sandwiched between a sulfur atomic layer thereon and a sulfur atomic layer thereunder, and for example, one molybdenum atom may be bonded to three sulfur atoms thereon and three sulfur atoms thereunder by covalent bond within a unit cell.

In one or more example embodiments, as the 2D material layer 120 includes 2D sheets of 2 to 5 layers, the 2D material layer 120 may have a first thickness t1 of about 1.5 nanometers to about 3.5 nanometers. In one or more example embodiments, the 2D material layer 120 may be conformally formed on the first surface 110A of the semiconductor substrate 110 by using a chemical vapor deposition process, and may have a relatively large area to cover the entire top surface of the doped region 110P.

The 2D material layer 120 may form the hybrid photodiode HPD of a 2D/3D structure together with the doped region 110P of the 3D bulk semiconductor substrate 110 disposed thereunder. For example, the doped region 110P of the semiconductor substrate 110 has P-type conductivity and the 2D material layer 120 has n-type conductivity, the 2D material layer 120 and the doped region 110P of the semiconductor substrate 110 may form a p-n diode. The 2D material layer 120 has the relatively small first thickness t1 and is two-dimensionally disposed, such that a depletion region of a relatively narrow width extending two-dimensionally may be provided between the 2D material layer 120 and the doped region 110P of the semiconductor substrate 110. In one or more example embodiments, the depletion region may have a relatively narrow width ranging from 1 nanometer to 10 nanometers. In one or more example embodiments, the depletion region may have a relatively narrow width ranging from 1 nanometer to several nanometers.

The top absorber 130 may be disposed on the 2D material layer 120. The top absorber 130 may include graphene. In one or more example embodiments, the top absorber 130 may include a monolayer of graphene. For example, the top absorber 130 may be disposed to cover the entire top surface of the 2D material layer 120. When the top absorber 130 includes the monolayer of graphene, the top absorber 130 may have a second thickness t2 of about 0.1 nanometer to about 1 nanometer.

The top absorber 130 may function as a carrier absorber that quickly absorbs electrons and transmits them to a first electrode 142 when an electron-hole pair is excited from light formed in the 2D material layer 120 and the doped region 110P. Moreover, the top absorber 130 may function as an electron-hole pair multiplication member according to a unique energy band property. In this case, a strong electric field has to be applied within graphene such that multiple carriers generated in graphene are quickly separated and collected by an electrode before they are recombined. In this regard, the strong electric field caused by the reverse voltage applied between the 2D material layer 120 and the doped region 110P extends to graphene, enabling the multiple carriers formed in graphene to be effectively collected.

The top absorber 130 is described as including the monolayer of graphene, but in one or more example embodiments, the top absorber 130 may also include a graphene 2D sheet of two or more layers as long as the top absorber 130 functions as a carrier absorber and an electron-hole pair replication layer.

An element separation trench 112T may be formed in the semiconductor substrate 110 and an element separation film 112 may be disposed on an inner wall of the element separation trench 112T. The element separation film 112 may include an insulating material such as silicon oxide. The element separation trench 112T may be formed to pass through a part of the 2D material layer 120, such that the 2D material layer 120 may not be disposed on a top surface of the element separation film 112. However, in one or more example embodiments, the 2D material layer 120 may extend to the top surface of the element separation film 112.

The top absorber 130 may extend to the top surface of the element separation film 112, and the first electrode 142 may be disposed on the top absorber 130 disposed on the element separation film 112. The first electrode 142 may be electrically connected to the top absorber 130. In one or more example embodiments, the first electrode 142 may include, but is not limited to, at least one of chrome, gold, aluminum, cobalt, copper, and nickel.

The second electrode 144 may be disposed on the second surface 110B of the semiconductor substrate 110. The second electrode 144 may include, but is not limited to, at least one of chrome, gold, aluminum, cobalt, copper, and nickel.

The image sensor 100 according to one or more example embodiments may further include additional components such as a floating diffusion region that accumulates electrons collected from the hybrid photodiode HPD, a pixel transistor for applying a voltage to the hybrid photodiode HPD, a pixel element separation film that separates the semiconductor substrate 110 into a plurality of pixel regions, a red-green-blue (RGB) color filter corresponding to each pixel region, a micro-lens that collects the incident light into each pixel region, etc.

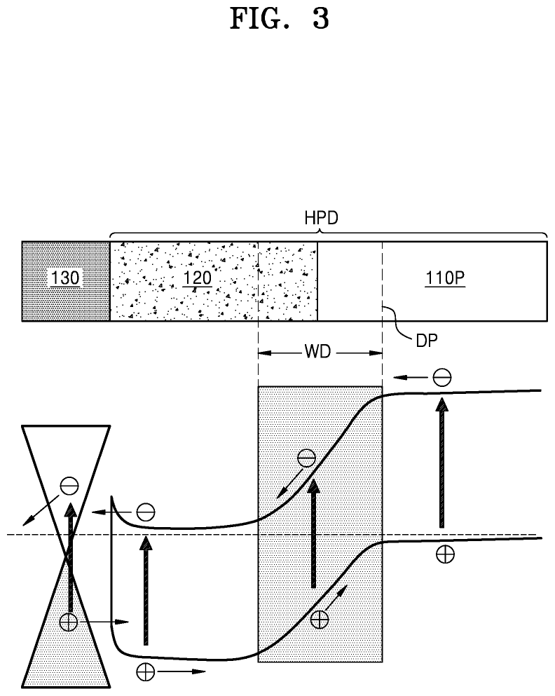

FIG. 3 is a schematic view showing a schematic energy band structure of an image sensor according to one or more example embodiments. In FIG. 3, a schematic energy band structure of the hybrid photodiode HPD of FIG. 1 and a part of the top absorber 130 placed thereon are shown.

Referring to FIG. 3, the hybrid photodiode HPD formed of a 3D p-type silicon substrate (i.e., the doped region 110P) and the n-type 2D material layer 120 may have bending of an energy band in a junction region therebetween. As shown in FIG. 3, carriers corresponding to generation of an electron-hole pair may be generated by photon absorption in all regions of the top absorber 130 including graphene, the 2D material layer 120, and the doped region 110P.

For example, a depletion region DP may be formed in the junction region between the 3D p-type silicon substrate (i.e., the doped region 110P) and the n-type 2D material layer 120, and an electric field may be generated in the depletion region DP. Because the n-type 2D material layer 120 is formed to have a relatively small thickness t1 (see FIG. 1), a width WD of the depletion region DP may also be small and a relatively large electric field may be generated in the depletion region DP due to a corresponding spatial limitation. As a result, the electron-hole pair may be quickly separated in the depletion region DP.

Moreover, the width WD of the depletion region DP is relatively small, for example, as having a range of 1 nanometer to several nanometers, such that a surface charge may be generated on the outside of the 2D material layer 120 and may have an influence upon the energy band of the top absorber 130.

The top absorber 130 including a graphene monolayer may have an energy band structure where two cones meet at a vertex (e.g., a Dirac point). When a single photon is excited in the top absorber 130, the excited photon may have a high kinetic energy and may induce carrier multiplication. As a result, even when one photon is excited, two electron carriers may be generated for one photon.

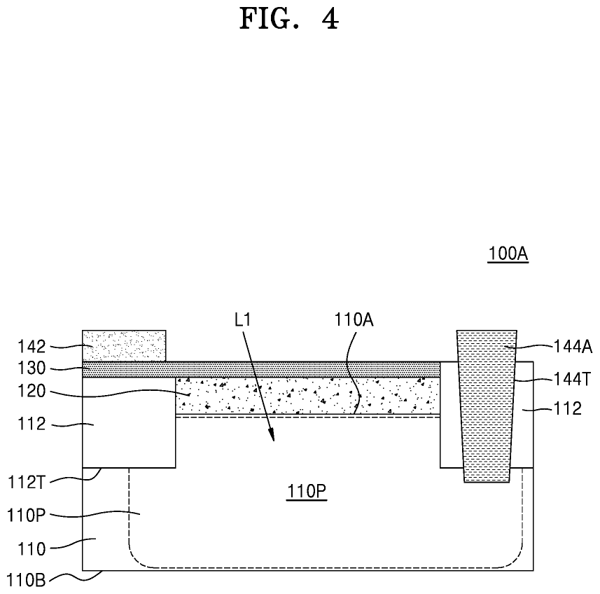

FIG. 4 is a cross-sectional view showing an image sensor 100A according to one or more example embodiments.

Referring to FIG. 4, both the first electrode 142 and a second electrode 144A may be disposed on the first surface 110A of the semiconductor substrate 110. For example, the second electrode 144A may be disposed in a trench 144T passing through the element separation film 112. The second electrode 144A may be disposed to contact the semiconductor substrate 110 or the doped region 110P on a bottom surface thereof and thus may be electrically connected to the doped region 110P. The second electrode 144A may be surrounded by the element separation film 112 and thus may be electrically insulated from the 2D material layer 120 and/or the top absorber 130.

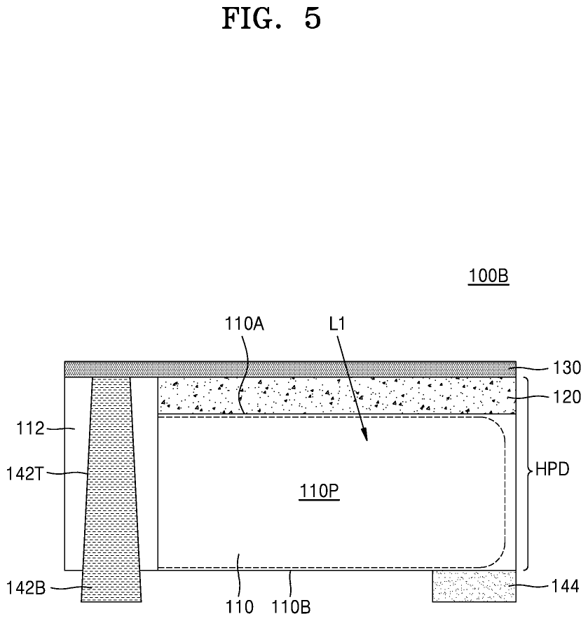

FIG. 5 is a cross-sectional view showing an image sensor 100B according to one or more example embodiments.

Referring to FIG. 5, both a first electrode 142B and the second electrode 144 may be disposed on the second surface 110B of the semiconductor substrate 110, and the first electrode 142B may pass through the semiconductor substrate 110. For example, the first electrode 142B may be disposed in a trench 142T passing through the element separation film 112. A top surface of the first electrode 142B may be disposed to contact a bottom surface of the top absorber 130 and may be electrically connected to the top absorber 130 and/or the 2D material layer 120. The first electrode 142B may be surrounded by the element separation film 112 and thus may be electrically insulated from the semiconductor substrate 110 or the doped region 110P.

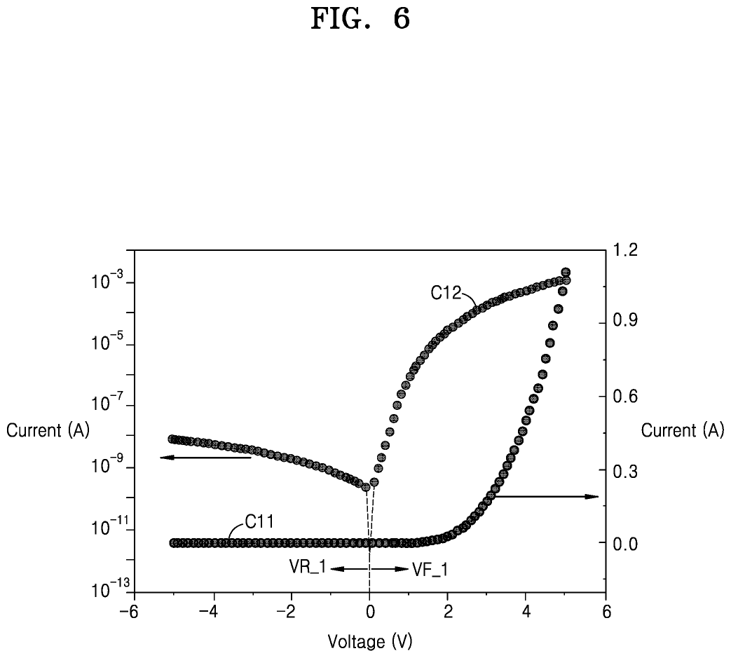

FIG. 6 is a graph showing a voltage-current behavior of an image sensor according to one or more example embodiments.

FIG. 6 shows current-voltage curves C11 and C12 of the image sensor having the structure of FIG. 1 in a state where light is not applied. As shown in a forward current-voltage curve C11, in a forward voltage section VF_1, e.g., a voltage range having positive values, a relatively high current of up to several milliamperes (mA) has been obtained. As shown in a reverse current-voltage curve C12, in a reverse voltage section VR_1, e.g., a voltage range having negative values, a current of several to several tens of nanoamperes (nA) has been obtained. Thus, it may be seen that the image sensor having the structure of FIG. 1 has diode rectification characteristics.

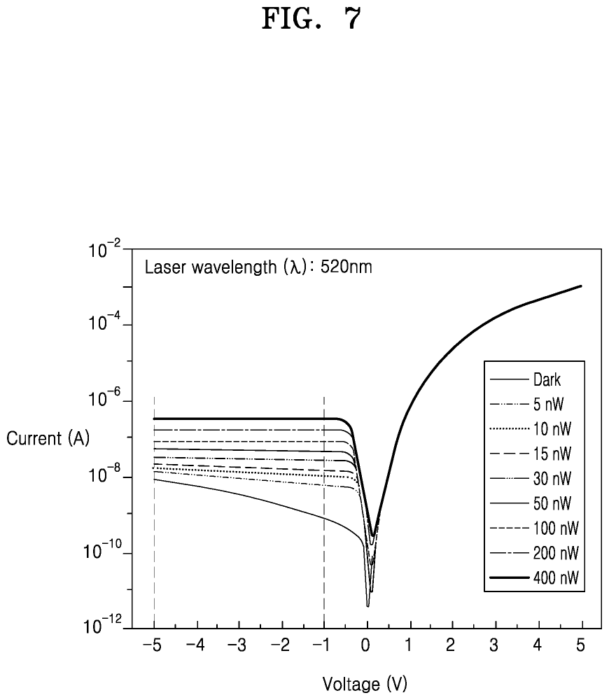

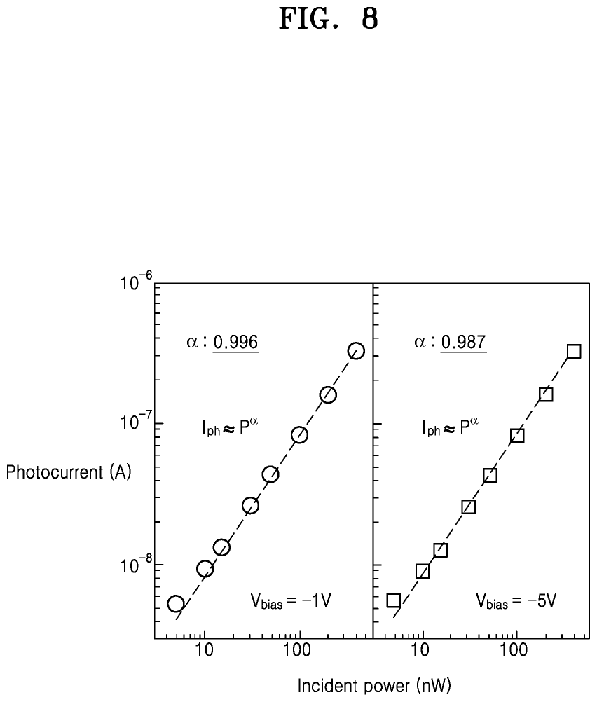

FIG. 7 is a graph showing a voltage-photocurrent behavior of an image sensor according to one or more example embodiments. FIG. 8 is a graph showing a photocurrent with respect to an incident power of an image sensor according to one or more example embodiments.

FIG. 7 shows a voltage-current curve with respect to an incident power when a light having a short wavelength of about 520 nm is applied to the image sensor. As shown in

FIG. 7, as a power of incident light irradiated to the image sensor increases, a photocurrent sequentially increases in the reverse voltage section VR_1.

FIG. 8 shows one or more example embodiments wherein the amount of photocurrent with respect to an incident power on a logarithmic scale when a reverse bias voltage is about −1 and about −5 V. As shown in FIG. 8, for both a reverse bias voltage of about −1 V and a reverse bias voltage of about −5 V, the amount of photocurrent with respect to an incident power significantly matches a power law equation, and in the respective cases, the amount of photocurrent with respect to the incident power has been plotted using matching indices α of about 0.996 and about 0.987, respectively. When α is close to 1, it may mean that a high-efficiency photocurrent is generated for an incident power.

It may be seen that an image sensor according to one or more example embodiments shows a photocurrent linearly increasing with an incident power and exhibits a reliable photoelectric conversion property, especially in a relatively low operating voltage (e.g., a relatively low reverse bias voltage like −1 V).

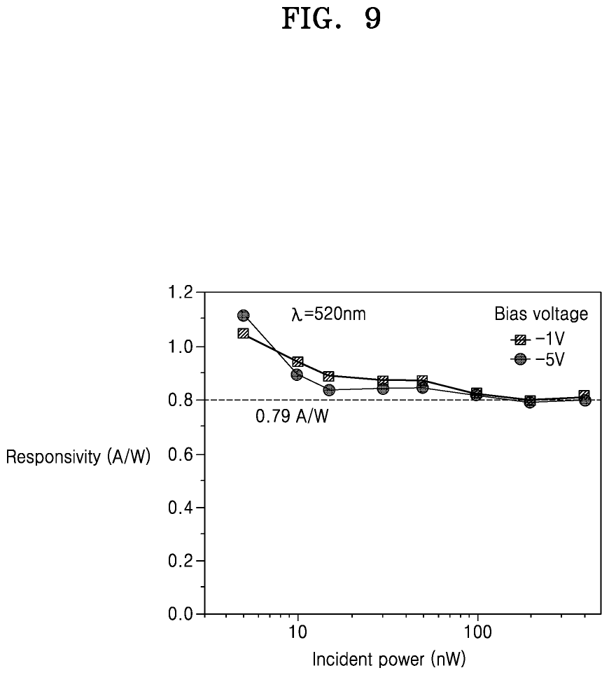

FIG. 9 is a graph showing responsivity of an image sensor according to one or more example embodiments.

Referring to FIG. 9, for both a reverse bias voltage of about −1 V and a reverse bias voltage of about −5 V, even when an incident power increases from about 5 nW to about 400 nW, a responsivity is higher than that of commercial silicon p-n diodes of 0.79 A/W or more. It may be seen that an image sensor according to one or more example embodiments shows a relatively high responsivity regardless of an incident power and exhibits a reliable photoelectric conversion property, especially in a relatively low operating voltage (e.g., a relatively low reverse bias voltage like −1 V).

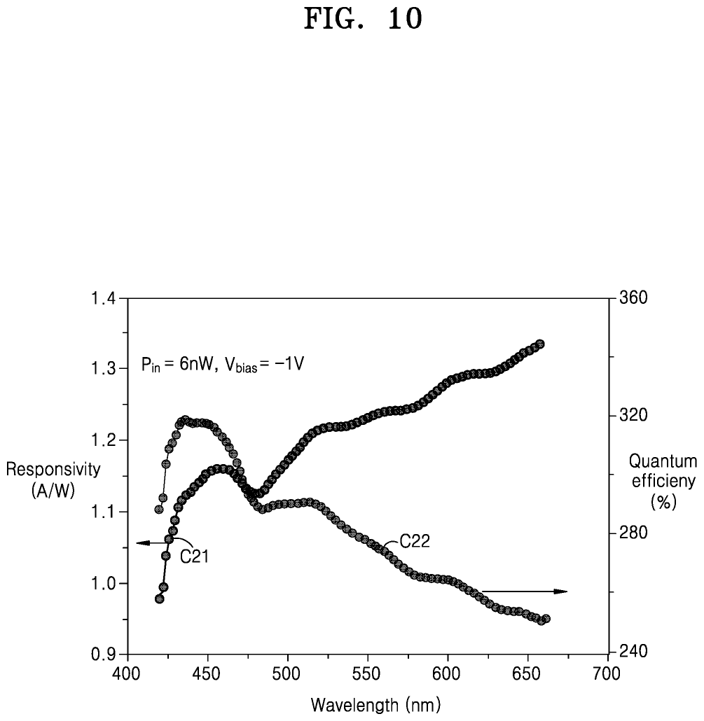

FIG. 10 is a graph showing responsivity and a quantum efficiency with respect to an incident light wavelength of an image sensor according to one or more example embodiments.

In FIG. 10, a responsivity C21 with respect to an incident light wavelength of the image sensor and a quantum efficiency C22 with respect to the incident light wavelength are shown. A photocurrent in an incident light wavelength range of about 420 nm to about 670 nm is measured using a reverse bias voltage of about −1 V in an incident power of about 6 nW, from which a responsivity and a quantum efficiency are calculated and plotted.

As shown in FIG. 10, an image sensor according to one or more example embodiments shows a relatively high responsivity of about 1.0 A/W or more in the entire wavelength range of a visible light region. In comparison to a case where an existing photodiode based on silicon has a responsivity of 0.4 to 0.6 A/W, the hybrid photodiode according to one or more example embodiments has a significantly high responsivity. It may be assumed that this is because a relatively strong electric field is formed by a depletion region of a narrow width, enabling rapid separation of an electron-hole pair and generation of carriers.

Moreover, the image sensor according to one or more example embodiments may have a quantum efficiency (or an external quantum efficiency (EQE)) greater than 100%. As shown in FIG. 10, the image sensor according to one or more example embodiments shows a remarkably high quantum efficiency (or an external quantum efficiency) corresponding to about 240% to about 320% in the entire wavelength range of the visible light region. In comparison to a case where the existing photodiode based on silicon has a quantum efficiency (or external quantum efficiency) of about 70% to about 90%, the hybrid photodiode according to one or more example embodiments has a significantly high quantum efficiency. It may be assumed that this is because not only formation of a relatively strong electric field due to a depletion region of a narrow width enables rapid separation of an electron-hole pair and generation of carriers, but also a top absorber of a graphene monolayer covering the entire top surface of the hybrid photodiode acts as a carrier multiplication member.

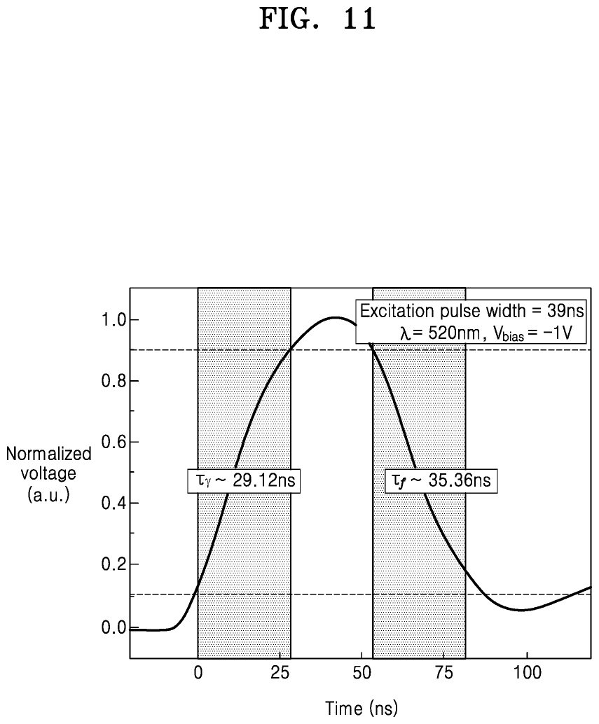

FIG. 11 is a graph showing a response time of an image sensor according to one or more example embodiments.

Referring to FIG. 11, an incident light in a wavelength range of about 520 nm is irradiated using a pulse width of about 39 ns at a reverse bias voltage of about −1 V. The image sensor according to one or more example embodiments has a rise time of about 29.12 ns and a drop time of about 35.36 ns. In comparison to a photodiode based on silicon, the hybrid photodiode according to one or more example embodiments has a higher spectral sensitivity than an existing commercial semiconductor while having fast response speed and response time.

As described above with reference to one or more example embodiments shown in FIGS. 6, 7, 8, 9 and 11, the image sensor according to one or more example embodiments may have a hybrid photodiode structure forming a depletion region with a relatively narrow width and may further include a top absorber of a graphene monolayer covering the entire top surface of a 2D material layer. As a strong electric field is formed by a depletion region with a relatively narrow width, an electron-hole pair may be separated at high speed and thus carriers may be collected through the top absorber. The top absorber may function as a carrier multiplication member, thereby obtaining a remarkably high quantum efficiency. Therefore, the image sensor according to one or more example embodiments shows a fast response speed and a high responsivity in a low-light environment.

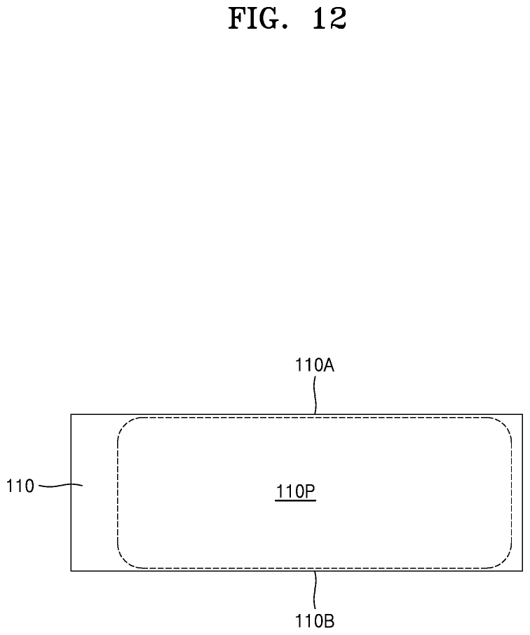

FIGS. 12, 13 and 14 are cross-sectional views showing a method of manufacturing the image sensor 100 according to one or more example embodiments.

Referring to FIG. 12, according to one or more example embodiments, the semiconductor substrate 110 may be provided. The semiconductor substrate 110 may include the first surface 110A and the second surface 110B. Thereafter, a p-type impurity may be injected to the semiconductor substrate 110 such that the doped region 110P may be formed. The doped region 110P may be a region doped with a p-type impurity such as boron or gallium.

The semiconductor substrate 110 may have a reduced thickness, by being ground before the doped region 110P is formed, or by being ground in a part thereof from the second surface 110B after the doped region 110P is formed by injecting an impurity onto the first surface 110A of the semiconductor substrate 110. A support substrate may be attached to the second surface 110B of the semiconductor substrate 110.

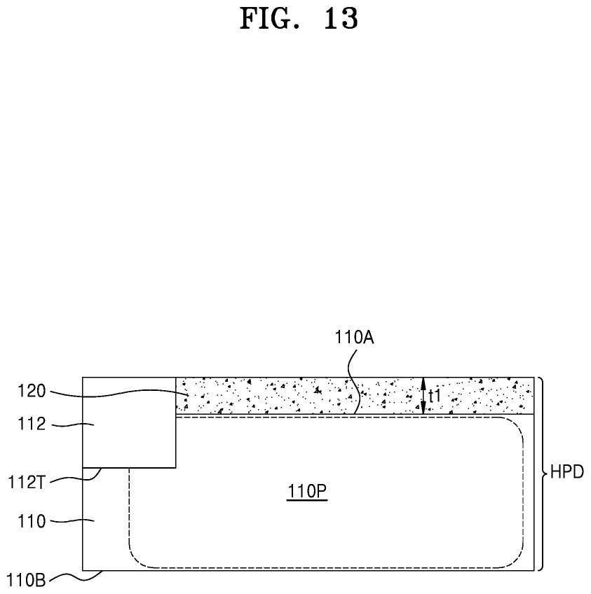

Referring to one or more example embodiments shown in FIG. 13, the 2D material layer 120 may be formed on the first surface 110A of the semiconductor substrate 110.

In one or more example embodiments, the 2D material layer 120 may include molybdenum disulfide (MoS₂), and may be formed using, for example, a chemical vapor deposition process such as a metal organic chemical vapor deposition process. In one or more example embodiments, the 2D material layer 120 may be formed using a first precursor including molybdenum and a second precursor including sulfur. In one or more example embodiments, the first precursor may include at least one of Mo, MoO₃, MoF₆, MoCl₆, and Mo(CO)₆. For example, a process of forming the 2D material layer 120 may be performed at a temperature of about 300° C. to about 700° C.

In one or more example embodiments, the 2D material layer 120 may include 2D sheets of 2 to 5 layers and may have the first thickness t1 of about 1.5 nanometers to about 3.5 nanometers.

In one or more example embodiments, the 2D material layer 120 may be formed using an atomic layer deposition process, an evaporation process, etc.

Thereafter, a mask pattern may be formed on the 2D material layer 120 and the semiconductor substrate 110, a part of the 2D material layer 120 and the semiconductor substrate 110 may be removed using the mask pattern as an etch mask to form the element separation trench 112T, and an insulating material may be filled in the element separation trench 112T to form the element separation film 112.

In one or more example embodiments, the element separation film 112 may be formed on the semiconductor substrate 110 before the 2D material layer 120 is formed, and the 2D material layer 120 may be formed on the semiconductor substrate 110 and the element separation film 112.

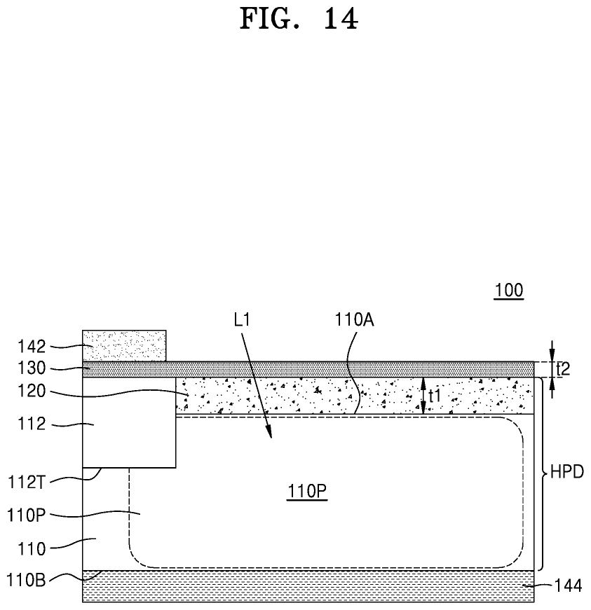

Referring to one or more example embodiments shown in FIG. 14, the top absorber 130 may be formed on the 2D material layer 120. In one or more example embodiments, the top absorber 130 may include a monolayer of graphene.

For example, the top absorber 130 may be formed using a chemical vapor deposition process. The chemical vapor deposition process may include any one of low pressure chemical vapor deposition (LPCVD), atmosphere pressure chemical vapor deposition (APCVD), or plasma enhanced pressure chemical vapor deposition (PECVD). The chemical vapor deposition process may be performed using a hydrocarbon-based precursor such as, but not limited to, methane, benzene, toluene, pyridine, naphthalene, etc., at a temperature of about 800° C. to about 1100° C.

Thereafter, the first electrode 142 may be formed on the top surface of the top absorber 130. In one or more example embodiments, the first electrode 142 may be formed on a part of the top absorber 130 placed on the top surface of the element separation film 112, such that the first electrode 142 may be formed at a position vertically overlapping the element separation film 112. The first electrode 142 may be formed using at least one of chrome, gold, aluminum, cobalt, copper, and nickel.

Thereafter, the semiconductor substrate 110 may be turned over such that the second surface 110B thereof may face upward. The second electrode 144 may be disposed on the second surface 110B of the semiconductor substrate 110. In one or more example embodiments, the second electrode 144 may be formed using at least one of chrome, gold, aluminum, cobalt, copper, and nickel.

The image sensor 100 may be formed by performing the above-described process, but one or more example embodiments are not limited thereto.

According to the method of manufacturing the image sensor 100 described above according to one or more example embodiments, the 2D material layer 120 and the top absorber 130 may be formed over a relatively large area through the chemical vapor deposition process. The image sensor 100 may have a fast response speed and an excellent quantum efficiency.

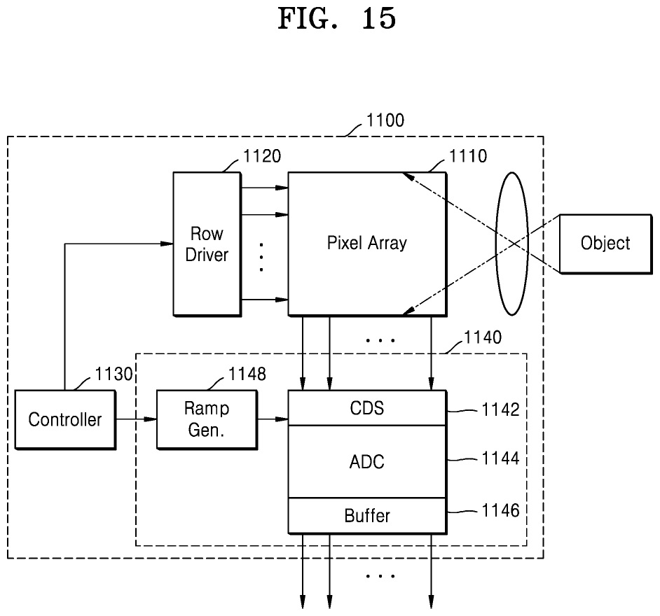

FIG. 15 is a block diagram of an image sensor 1100 according to one or more example embodiments.

Referring to FIG. 15, the image sensor 1100 may include a pixel array 1110, a controller 1130, a row driver 1120, and a pixel signal processing unit 1140. The image sensor 1100 may include the above-described image sensor 100.

The pixel array 1110 may include a plurality of unit pixels arranged two-dimensionally, each of which may include a photoelectric conversion element. The photoelectric conversion element may absorb light to generate electric charges in which an electrical signal (an output voltage) corresponding to the generated electric charges may be provided to the pixel signal processing unit 1140 through a vertical signal line. Unit pixels included in the pixel array 1110 may provide an output voltage at a time in the unit of a row, such that unit pixels included in one row of the pixel array 1110 may be simultaneously activated by a selection signal output by the row driver 1120. Unit pixels included in a selected row may provide an output voltage corresponding to absorbed light to an output line of a corresponding column.

The controller 1130 may control the row driver 1120 such that the pixel array 1110 absorbs light to accumulate electric charges or temporarily stores the accumulated electric charges and outputs an electrical signal corresponding to the stored electric charges outside the pixel array 1110. The controller 1130 may control the pixel signal processing unit 1140 to measure the output voltage provided by the pixel array 1110.

The pixel signal processing unit 1140 may include a correlated double sampler (CDS) 1142, an analog-to-digital converter (ADC) 1144, and a buffer 1146. The CDS 1142 may sample and hold the output voltage provided from the pixel array 1110. The CDS 1142 may perform double sampling on a specific noise level and a level corresponding to the generated output voltage to output a level corresponding to a difference therebetween. The CDS 1142 may receive a ramp signal generated by a ramp signal generator 1148 and compare them to output a comparison result.

The ADC 1144 may convert an analog signal corresponding to the level received from the CDS 1142 into a digital signal. The buffer 1146 may latch the digital signal, and a latched signal may be sequentially output outside the image sensor 1100 so as to be transmitted to an image processor.

One or more example embodiments have been described above with reference to the drawings. Although one or more example embodiments have been described using specific terms, such specific terms are merely used for the purpose of explaining one or more example embodiments, and such terms are not used to limit the scope of one or more example embodiments. It will be apparent to those of ordinary skill in the art that various modifications and other equivalent one or more example embodiments are possible.

Although one or more example embodiments have been particularly shown and described above, it will be apparent to those skilled in the art that various changes in form and details may be made therein without departing from the spirit and scope of the following claims.

What is claimed is:

1. An image sensor comprising:
a semiconductor substrate comprising a top surface and a bottom surface;
a two-dimensional (2D) material layer on the top surface of the semiconductor substrate and comprising molybdenum disulfide (MoS₂); and
a top absorber on a top surface of the 2D material layer and comprising graphene,
wherein the semiconductor substrate comprises silicon doped with a p-type impurity,
wherein the 2D material layer has n-type conductivity, and
wherein the semiconductor substrate and the 2D material layer are configured to form a p-n diode.

2. The image sensor of claim 1, wherein the 2D material layer comprises 2D sheets comprising from two to five layers stacked in a vertical direction on the top surface of the semiconductor substrate.

3. The image sensor of claim 1, wherein the top absorber comprises a monolayer of graphene.

4. The image sensor of claim 1, wherein the 2D material layer has a thickness in a range of from about 1.5 nanometers to about 3.5 nanometers.

5. The image sensor of claim 1, further comprising:
a first electrode on the top absorber and electrically connected to the 2D material layer; and
a second electrode electrically connected to the semiconductor substrate.

6. The image sensor of claim 1, wherein the semiconductor substrate comprises a doped region, and
wherein the doped region comprises a p-type impurity.

7. The image sensor of claim 6, wherein the doped region and the 2D material layer are configured to form a narrow-width depletion region in a junction portion between the doped region and the 2D material layer.

8. The image sensor of claim 1, wherein the image sensor has an external quantum efficiency (EQE) greater than 100%.

9. The image sensor of claim 1, wherein the top absorber has a thickness ranging from 0.1 nanometers to 1 nanometer.

10. The image sensor of claim 1, wherein the top absorber covers an entirety of the top surface of the 2D material layer.

11. An image sensor comprising:
a semiconductor substrate comprising a top surface and a bottom surface;
a two-dimensional (2D) material layer on the top surface of the semiconductor substrate and comprising molybdenum disulfide (MoS₂); and
a top absorber on a top surface of the 2D material layer and comprising graphene,
wherein the 2D material layer comprises 2D sheets comprising from two to five layers stacked in a vertical direction on the top surface of the semiconductor substrate, and
wherein the top absorber comprises a monolayer of graphene.

12. The image sensor of claim 11, wherein the 2D material layer has a thickness in a range of from about 1.5 nanometers to about 3.5 nanometers.

13. The image sensor of claim 11, further comprising:
a first electrode on the top absorber and electrically connected to the 2D material layer; and
a second electrode on the bottom surface of the semiconductor substrate.

14. The image sensor of claim 11, wherein the semiconductor substrate comprises silicon doped with a p-type impurity,
wherein the 2D material layer has n-type conductivity, and
wherein the semiconductor substrate and the 2D material layer are configured to form a p-n diode.

15. The image sensor of claim 14, wherein the semiconductor substrate comprises a doped region, and
wherein the doped region and the 2D material layer are configured to form a narrow-width depletion region in a junction portion between the doped region and the 2D material layer.

16. The image sensor of claim 11, wherein the image sensor has an external quantum efficiency (EQE) greater than 100%.

17. The image sensor of claim 11, wherein the top absorber has a thickness in a range of from 0.1 nanometers to 1 nanometer, and
wherein the top absorber covers an entirety of the top surface of the 2D material layer.

18. An image sensor comprising a plurality of pixels, wherein each of the plurality of pixels comprises:
a doped region in a semiconductor substrate and comprising a p-type impurity;
a two-dimensional (2D) material layer on a top surface of the semiconductor substrate and comprising molybdenum disulfide (MoS₂);
a top absorber on a top surface of the 2D material layer and comprising graphene;
a first electrode on the top absorber; and
a second electrode on a bottom surface of the semiconductor substrate and electrically connected to the doped region,
wherein the 2D material layer comprises 2D sheets comprising from two to five layers stacked in a vertical direction on the top surface of the semiconductor substrate, and
wherein the top absorber comprises a monolayer of graphene.

19. The image sensor of claim 18, wherein each of the plurality of pixels further comprises an element separation film disposed in an element separation trench extending from the top surface of the semiconductor substrate into the semiconductor substrate,
wherein a part of the top absorber is disposed on the element separation film, and
wherein the first electrode is disposed on the part of the top absorber.

20. The image sensor of claim 18, wherein the doped region and the 2D material layer are configured to form a narrow-width depletion region in a junction portion between the doped region and the 2D material layer.
